(19) United States
(12) Patent Application Publication
(10) Pub. No.: US 2025/0232944 A1
(43) Pub. Date: Jul. 17, 2025

(54) MULTIPOLE LENS AND CHARGED PARTICLE BEAM DEVICE

(71) Applicant: Hitachi High-Tech Corporation, Tokyo (JP)

(72) Inventors: Shun KIZAWA, Tokyo (JP); Kohei SUZUKI, Tokyo (JP); Daisuke BIZEN, Tokyo (JP); Yuzuru MIZUHARA, Tokyo (JP); Shunsuke MIZUTANI, Tokyo (JP); Takafumi MIWA, Tokyo (JP)

(21) Appl. No.: 18/699,609

(22) PCT Filed: Dec. 7, 2021
(86) PCT No.: PCT/JP2021/044948

§ 371 Date: Apr. 9, 2024

(51) Int. Cl. H01J 37/12; H01J 37/147

(52) U.S. Cl. CPC H01J 37/12; H01J 37/1472; H01J 2237/1202; H01J 2237/1534

(57) ABSTRACT

A multipole lens includes a hollow cylindrical non-magnetic bobbin provided with a plurality of slits, and a metal wire. The plurality of slits are disposed such that a central angle between adjacent slits is (360/12N)°, N being a natural number. Winding numbers of the metal wire in the plurality of slits are equal. When a cross section of the non-magnetic bobbin orthogonal to a longitudinal direction of the slits is divided into an even number of regions having an equal central angle and including two or more of the slits, directions in which the metal wire passes through the slits provided in the region are same, and a direction in which the metal wire passes through the slits provided in the adjacent region is reversed.

### TECHNICAL FIELD

The present invention relates to a multipole lens and a charged particle beam device.

### BACKGROUND ART

In the most advanced semi-conductor process using an extreme ultraviolet (EUV) lithography technique, it is important to efficiently detect and manage a Stochastic defect caused by shot noise of an EUV light source and non-uniformity of a resist material in order to improve a manufacturing yield. Since a size of the Stochastic defect reaches a nanometer size, a charged particle beam device having a resolution equal to or higher than that of the defect size is used for the detection. In addition, since an occurrence probability of the Stochastic defect may be one millionth or less, a throughput for measuring a large number of measurement points in a short time is required.

PTL 1 proposes a coil winding method for minimizing a multipole field in a saddle type deflection coil. The winding method is known as cosine distribution winding. By using the saddle type deflection coil having the cosine distribution winding, it is possible to implement charged particle beam deflection in which an aberration caused by the multipole field is prevented.

PTL 2 proposes a method in which an ExB filter including a multipole lens using magnetic poles is disposed and a deflection color aberration is corrected by appropriately controlling the ExB filter and a deflection coma aberration is corrected by appropriately controlling the multipole lens.

PTL 3 proposes a method in which a plurality of deflectors are disposed inside and outside an objective lens, and a beam is deflected by using a difference between a deflection color aberration coefficient and a deflection coma aberration coefficient of each deflector such that a deflection color aberration and a deflection coma aberration are not generated.

PTL 4 proposes a method in which a plurality of lenses and a deflector are disposed upstream of an objective lens, and a deflection aberration generated in the objective lens is cancelled by an off-axis aberration of the lens disposed upstream of the objective lens.

### CITATION LIST

### Patent Literature

PTL 1: JPS59-154732A
PTL 2: JP2001-15055A
PTL 3: JP2008-153131A
PTL 4: JP2015-95297A

### SUMMARY OF INVENTION

### Technical Problem

In order to increase a throughput of a charged particle beam device, an image shift function of performing imaging while repeating visual field movement (image shift) at a high speed is essential, but an image shift operation becomes a factor of deteriorating a spatial resolution due to a deflection color aberration and a deflection coma aberration generated in association.

In addition, in a semi-conductor process, in order to increase the number of chips to be acquired per wafer, patterning is performed up to a wafer end. On the other hand, it is difficult to perform lithography or etching at the wafer end and a yield tends to decrease, and there is a high need for inspection and measurement. However, when the wafer end is observed using the charged particle beam device, a retarding electric field necessary for a high resolution is disturbed due to discontinuity of a wafer surface, and a deflection field or a multipole field is generated. Accordingly, a deflection aberration such as a deflection coma aberration is generated, and therefore, when an SEM image of a semi-conductor wafer end portion is acquired, deterioration in a spatial resolution cannot be avoided.

Although it is possible to implement charged particle beam deflection, in which a high-order aberration caused by a multipole field is prevented, by using the technique described in PTL 1, remaining of deflection aberration caused by a dipole field is a problem. In order to solve this problem, it is necessary to correct the deflection aberration by some methods.

Although it is possible to correct a deflection aberration by using the techniques described in PTLs 2 to 4, any technique has a problem in complexity of hardware and a control system and manufacturing cost. Therefore, these methods are not suitable for applications in which cost reduction is important.

Since the technique described in PTL 2 uses a multipole lens capable of generating various multipole fields, a parasitic aberration such as a deflection astigmatism can also be corrected. On the other hand, since the multipole lens uses magnetic poles, there is a problem that a response delay specific to a magnetic material occurs. Therefore, it is difficult to perform control in conjunction with an image shift deflector that operates at a high speed.

In the technique described in PTL 3, since it is necessary to dispose a deflector inside the objective lens, a spatial restriction occurs. Therefore, mounting may be difficult depending on a structure of the objective lens.

Since a plurality of lenses are used, the technique described in PTL 4 is strongly affected by a parasitic aberration caused by an error in processing or assembly accuracy. Although this influence can be corrected in principle, complicated and high-cost control and structure are required.

The invention has been made in view of the above problems, and an object of the invention is to provide a multipole lens, which has a simple configuration and is capable of operating at a high speed, and a charged particle beam device including the multipole lens, in order to implement image shift deflection and observation of a wafer end portion without a deflection color and coma aberration.

### Solution to Problem

A multipole lens according to an embodiment of the invention includes a hollow cylindrical non-magnetic bobbin provided with a plurality of slits, and a metal wire, in which the non-magnetic bobbin includes a slit portion provided with the plurality of slits and first and second circumferential portions provided to sandwich the slit portion, and the plurality of slits are disposed such that a central angle between adjacent slits is (360/12N)°, N being a natural number, the metal wire is wound around the non-magnetic bobbin so as to repeat passing through a certain slit among the plurality of slits from the first circumferential portion toward the second circumferential portion, moving from the certain slit along the second circumferential portion to another slit among the plurality of slits, passing through the other slit from the second circumferential portion toward the first circumferential portion, and moving from the other slit along the first circumferential portion to still another slit among the plurality of slits, winding numbers of the metal wire in the plurality of slits are equal, and when a cross section of the non-magnetic bobbin orthogonal to a longitudinal direction of the slits is divided into an even number of regions having an equal central angle and including two or more of the slits, directions in which the metal wire passes through the slits provided in the region are same, and a direction in which the metal wire passes through the slits provided in the adjacent region is reversed.

### Advantageous Effects of Invention

The invention provides a multipole lens capable of correcting, at low cost and at a high speed, a deflection aberration generated during image shift deflection or observation of a wafer end portion, and a charged particle beam device using the multipole lens. Other problems and novel features will become apparent from the description of this specification and the accompanying drawings.

### BRIEF DESCRIPTION OF DRAWINGS

FIG. 1A is a cross-sectional view of a bobbin (slit portion).

FIG. 1B is a cross-sectional view of the bobbin (slit portion).

FIG. 1C is a diagram showing a winding method of a metal wire in a multipole lens.

FIG. 2A is a cross-sectional view showing a configuration of a hexapole lens.

FIG. 2B is a table showing a winding number distribution of the hexapole lens and simple calculation results of a dipole field and a hexapole field.

FIG. 3A is a cross-sectional view showing a configuration of a quadrupole lens.

FIG. 3B is a table showing a winding number distribution of the quadrupole lens and simple calculation results of the dipole field and a quadrupole field.

FIG. 4 is a cross-sectional view showing a configuration of a quadrupole lens-superimposed hexapole lens.

FIG. 5A is a cross-sectional view showing a configuration of a deflection coil-superimposed hexapole lens.

FIG. 5B is a cross-sectional view showing a configuration of a deflection coil-superimposed quadrupole lens.

FIG. 5C is a cross-sectional view showing a configuration of a deflection coil and quadrupole lens-superimposed hexapole lens.

FIG. 6A is a cross-sectional view showing a configuration of an ExB filter-superimposed hexapole lens.

FIG. 6B is a cross-sectional view showing a configuration of an ExB filter-superimposed quadrupole lens.

FIG. 6C is a cross-sectional view showing a configuration of an ExB filter and quadrupole lens-superimposed hexapole lens.

FIG. 7A is a diagram showing a configuration of a charged particle beam device according to a first example.

FIG. 7B is a diagram showing a configuration of the charged particle beam device according to the first example.

FIG. 8A is a diagram showing a configuration of a charged particle beam device according to a second example.

FIG. 8B is a diagram showing a configuration of the charged particle beam device according to the second example.

FIG. 9A is a diagram showing a configuration of a charged particle beam device according to a third example.

FIG. 9B is a diagram showing a configuration of the charged particle beam device according to the third example.

FIG. 10A is a diagram showing a configuration of a charged particle beam device according to a fourth example.

FIG. 10B is a diagram showing a configuration of the charged particle beam device according to the fourth example.

FIG. 11A is a diagram showing a configuration of a charged particle beam device according to a fifth example.

FIG. 11B is a diagram showing a configuration of the charged particle beam device according to the fifth example.

FIG. 12A is a table showing a winding number distribution of a multipole lens according to Embodiment 3.

FIG. 12B is a table showing a method of controlling the multipole lens according to Embodiment 3.

FIG. 12C is a table showing a winding number and simple calculation results of a dipole field and a hexapole field in a hexapole field generation mode.

FIG. 12D is a table showing a winding number and simple calculation results of a dipole field and a hexapole field in a dipole field generation mode.

FIG. 12E is a diagram showing a configuration of a charged particle beam device according to Embodiment 3.

### DESCRIPTION OF EMBODIMENTS

The present disclosure proposes a saddle-coil type multipole lens having a simple configuration and capable of operating at a high speed by winding a metal wire around a hollow cylindrical non-magnetic bobbin provided with a plurality of slits at equal angles while reversing a direction at every predetermined angle, and a charged particle beam device using the multipole lens.

### Embodiment 1

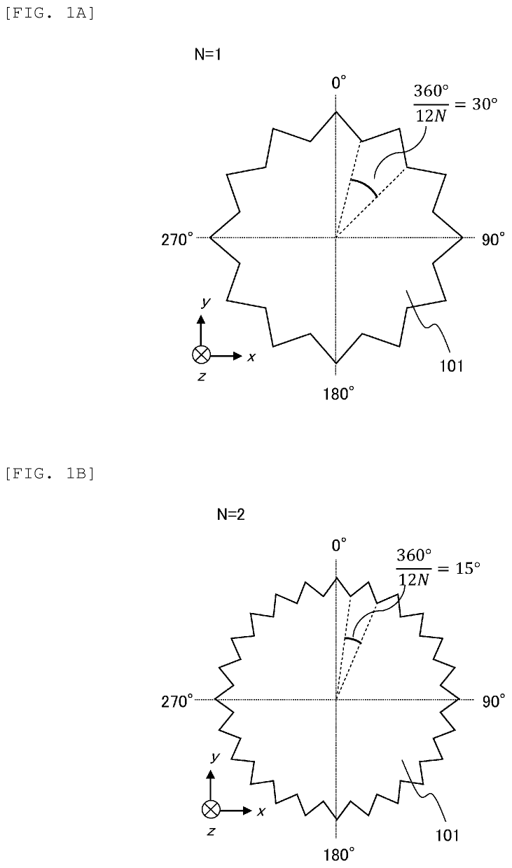

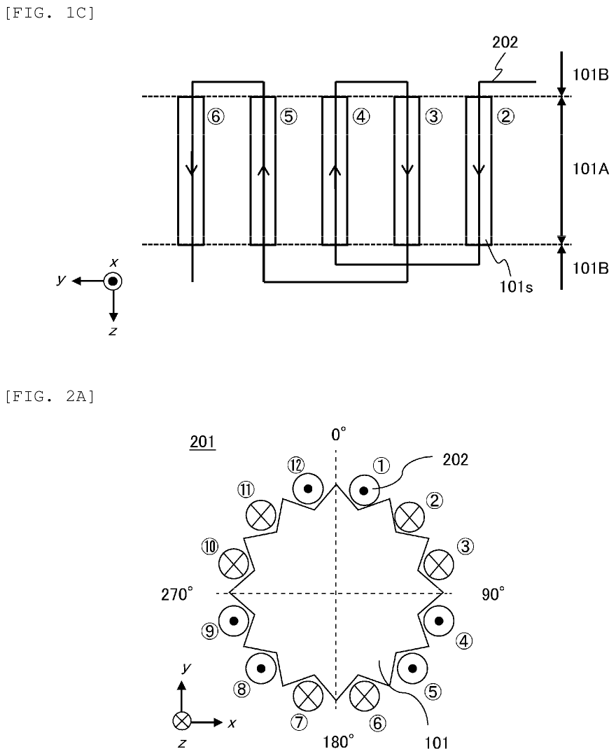

FIGS. 1A and 1B are each a cross-sectional view of a bobbin (slit portion) for winding a metal wire (coil) forming a multipole lens. A bobbin 101 forming the multipole lens according to an embodiment is provided with 12N (N is any natural number) slits along a circumference thereof, such that a central angle between adjacent slits is equal to (360/12N)°. In terms of mounting, since the slits are formed to have a width in a circumferential direction of the bobbin 101, a central angle between positions (deepest portions of the slits in slit shape examples of FIGS. 1A and 1B) at which the metal wire is disposed in adjacent slits may be (360/12N)°.

In the embodiment, in order to generate both a quadrupole field and a hexapole field at least, the number of slits provided in the bobbin 101 is a multiple of 12, which is a least common multiple of 4 and 6. FIG. 1A is a cross-sectional view when N=1, and FIG. 1B is a cross-sectional view when N=2. A hexapole lens or a quadrupole lens can be implemented by winding the metal wire around the slits provided in the bobbin 101 such that a winding number is the same in each slit while reversing a winding direction at every specific angle. More specifically, a winding method of the metal wire is as follows. A cross section of the bobbin 101 orthogonal to a longitudinal direction of the slits is divided into an even number of regions having an equal central angle and including two or more of the slits. At this time, the metal wire is wound around the bobbin 101 such that directions in which the metal wire passes through the slits provided in one region are same and a direction in which the metal wire passes through the slits provided in a region adjacent to the one region is reversed. By winding the metal wire in this manner, as will be described later, a hexapole field can be generated when the cross section of the bobbin 101 is divided into six regions, a quadrupole field can be generated when the cross section is divided into four regions, and a deflection field can be generated when the cross section is divided into two regions. By increasing N, it is possible to increase a sensitivity of a pole field generated by increasing a density of the metal wire present in one region. In addition, it is possible to reduce an influence of positional deviation of the metal wire.

The bobbin 101 is made of a non-magnetic material and has no core. Accordingly, it is possible to avoid a response delay specific to a magnetic material. In addition, the metal wire is insulation-coated so as not to be electrically conducted by contact between the metal wires or between the metal wire and the bobbin 101.

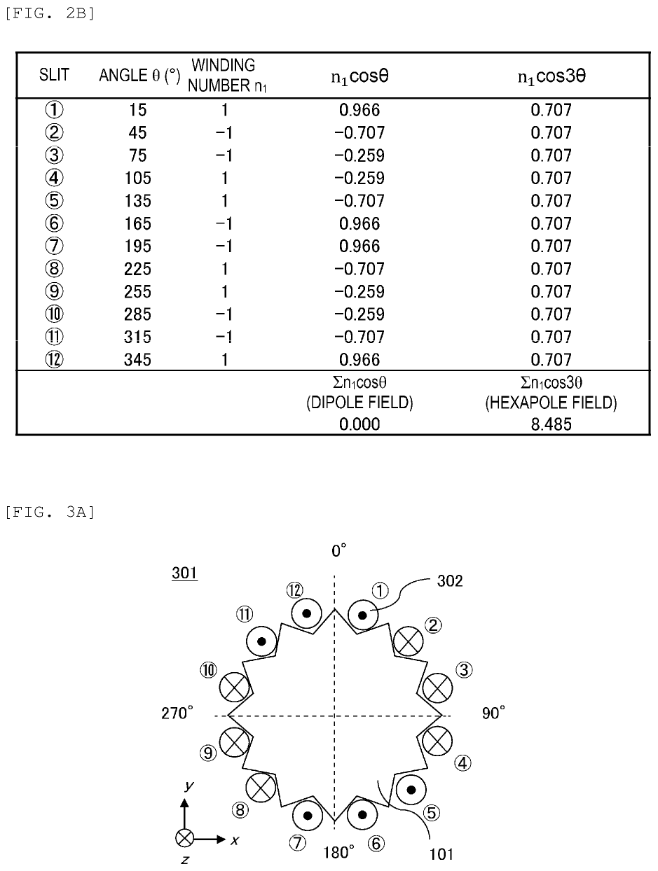

FIG. 2A shows a winding method of a coil when the hexapole field is generated. A multipole lens 201 that generates the hexapole field includes the bobbin 101 and a metal wire 202. The metal wire 202 is wound n₁ (n₁ is any natural number) times per slit while a passing direction through the slit is reversed every 60°. There is a possibility that a position of the metal wire 202 is deviated due to dimensional deviation, a manufacturing error, or the like. However, there is no problem when the angle is within a range of 60°±3°. FIG. 2A shows a configuration example when N=1 and n₁=1, but the embodiment is not limited to those conditions. Regardless of those values, a central angle between the metal wire in two slits respectively closest to boundaries with adjacent regions may be within a range of 60°±3°. However, N and n₁ are limited by actual design restrictions such as processing dimensions, and thus have finite values.

FIG. 2B is a table showing a winding number distribution of the multipole lens 201 shown in FIG. 2A and simple calculation results of a dipole field and the hexapole field. In the table of FIG. 2B, slit numbers in a first row are slit numbers assigned to the multipole lens 201. An angle θ in a second row indicates a position of the slit based on a 0° direction (y direction), and a clockwise direction is positive. A sign of a winding number in a third row corresponds to the passing direction of the metal wire 202 through the slit. In FIG. 2A, a case of passing toward the front side of the paper surface is positive, and a case of passing toward the back side of the paper surface is negative. Since the winding number n₁=1 in the multipole lens 201, an absolute value is 1 in any slit. A fourth row shows a product of the winding number n₁ and cos θ, and a fifth row shows a product of the winding number n₁ and cos 3θ. These integrated values are indices for explaining a magnitude of the dipole field and a magnitude of the hexapole field generated by the multipole lens 201.

According to the table of FIG. 2B, the multipole lens 201 generates the hexapole field without generating the dipole field. That is, the multipole lens 201 functions as a hexapole lens. This is because, while a sum of n₁ cos θ for all the slits is zero, a sum of n₁ cos 3θ for all the slits has a finite value. FIG. 2B shows a result when N=1 and n₁=1. This property is established for N and n₁ given by any natural number.

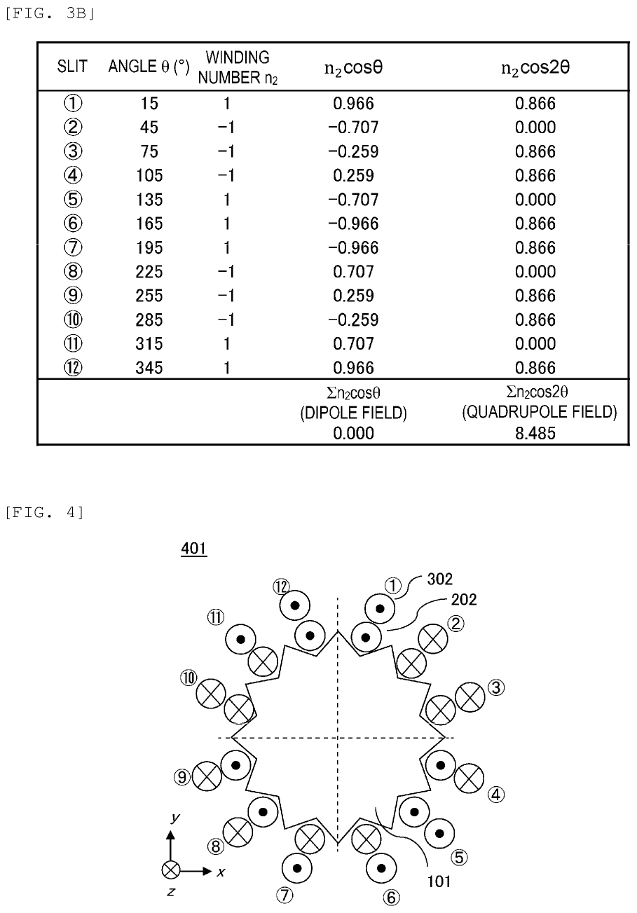

FIG. 3A shows a winding method of a coil when the quadrupole field is generated. A multipole lens 301 that generates the quadrupole field includes the bobbin 101 and a metal wire 302. The metal wire 302 is wound n₂ (n₂ is any natural number) times per slit while a passing direction through the slit is reversed every 90°. Even when a position of the metal wire 302 is deviated, there is no problem as long as the angle is within 90°±3°. FIG. 3A shows a configuration example when N=1 and n₂=1, but the embodiment is not limited to those conditions. Regardless of those values, a central angle between the metal wire in two slits respectively closest to boundaries with adjacent regions may be within a range of 90°±3°. However, N and n₂ are limited by actual design restrictions such as processing dimensions, and thus have finite values.

FIG. 3B is a table showing a winding number distribution of the multipole lens 301 shown in FIG. 3A and simple calculation results of the dipole field and the quadrupole field. In the table of FIG. 3B, slit numbers in a first row are slit numbers assigned to the multipole lens 301. The angle θ in a second row indicates a position of the slit based on the 0° direction (y direction), and a clockwise direction is positive. A sign of a winding number in a third row corresponds to the passing direction of the metal wire 302 through the slit. In FIG. 3A, a case of passing toward the front side of the paper surface is positive, and a case of passing toward the back side of the paper surface is negative. Since the winding number n₁=1 in the multipole lens 301, an absolute value is 1 in any slit. A fourth row shows a product of the winding number n₂ and cos θ, and a fifth row shows a product of the winding number n₂ and cos 2θ. These integrated values are indices for explaining a magnitude of the dipole field and a magnitude of the quadrupole field generated by the multipole lens 301.

According to the table of FIG. 3B, the multipole lens 301 generates the quadrupole field without generating the dipole field. That is, the multipole lens 301 functions as a quadrupole lens. This is because, while a sum of n₂ cos θ for all the slits is zero, a sum of n₂ cos 2θ for all the slits has a finite value. FIG. 2B shows a result when N=1 and n₂=1. This property is established for N and n₂ given by any natural number.

As described above, the multipole lens that generates the hexapole field and the multipole lens that generates the quadrupole field can be implemented by changing the winding number distribution of the coil.

The winding method of the metal wire (coil) in the multipole lens according to the embodiment will be described. FIG. 1C shows an example of the winding method of the metal wire in the multipole lens 201. FIG. 1C is a schematic diagram showing a side surface of the bobbin 101 which is developed on a plane. The bobbin 101 includes a slit portion 101A provided with a slit 101s and circumferential portions 101B for moving the metal wire to another slit above and below the slit portion 101A. Each time the metal wire passes through the slit, the metal wire moves to a different slit via the circumferential portion 101B of the bobbin, and repeats passing through the slit in a direction opposite to the previous passing direction. At this time, in each cycle of passing through the slit, moving to the circumferential portion, and passing through the slit, as the slit through which the metal wire passes next, a slit is selected such that a path on the circumference of the bobbin connecting the front and rear slits is shortest among the slits through which the metal wire passes in the direction opposite to the previous passing direction. The path on the circumference at this time may be forward or reverse. Similarly, the shortest path is selected for the path on the circumference through which the metal wire passes in each cycle. The winding method of the metal wire (coil) in the multipole lens is the same in the following modifications.

### Modification 1

FIG. 4 is a cross-sectional view showing a configuration of a multipole lens 401 according to Modification 1. The multipole lens 401 includes the bobbin 101, the hexapole lens metal wire 202, and the quadrupole lens metal wire 302. The metal wire 202 and the metal wire 302 are superimposed on the same bobbin 101, and the metal wire 202 and the metal wire 302 are controlled by respective controllers as described later. At this time, the metal wire 202 and the metal wire 302 are said to be independently superimposed on the bobbin 101.

In the multipole lens (quadrupole lens-superimposed hexapole lens) 401, both the quadrupole field and the hexapole field can be generated simultaneously and independently. Although FIG. 4 shows an example in which the quadrupole lens metal wire 302 is superimposed on the outside of the hexapole lens metal wire 202, the order of superimposition is not limited. The same applies to the following modifications.

### Modification 2

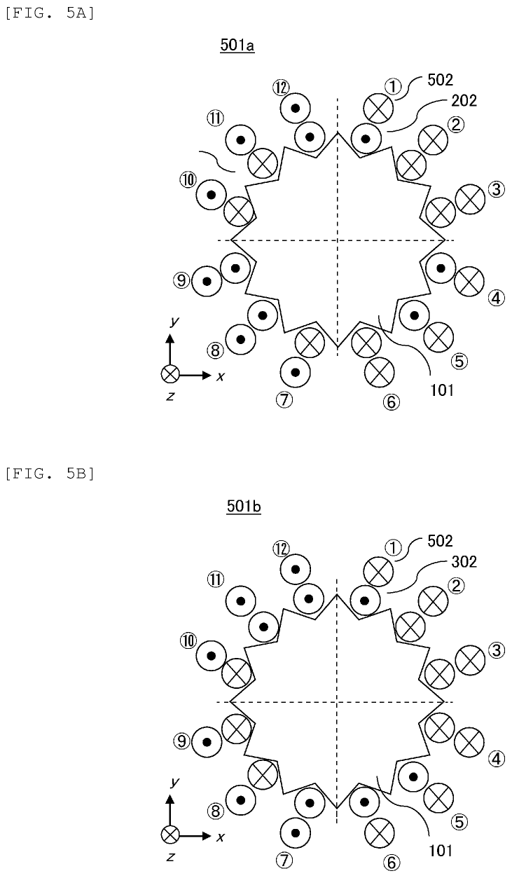

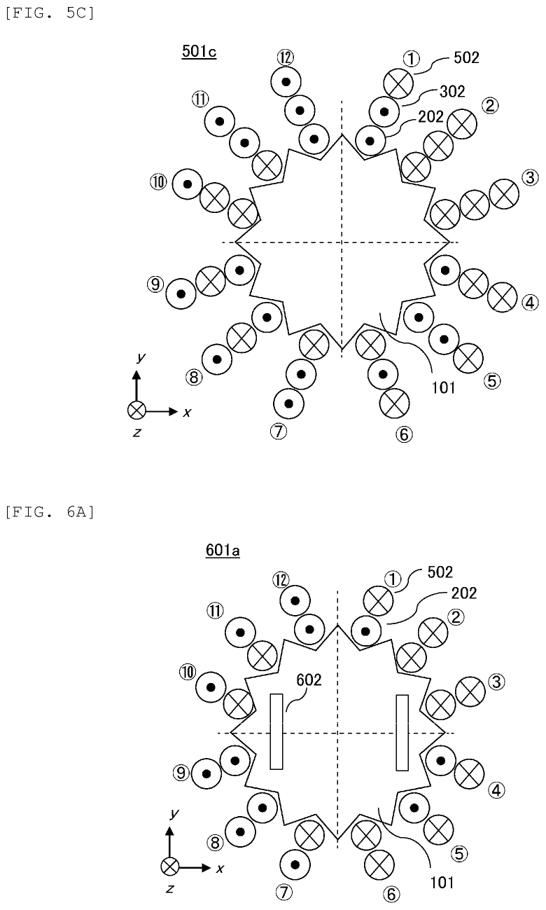

FIGS. 5A to 5C are cross-sectional views showing configurations of multipole lenses 501a to 501c according to Modification 2. The multipole lenses 501a to 501c are obtained by independently superimposing a deflection coil 502 on the multipole lenses 201, 301, and 401. That is, the multipole lens 501a includes the bobbin 101, the hexapole lens metal wire 202, and the deflection coil 502. The multipole lens 501b includes the bobbin 101, the quadrupole lens metal wire 302, and the deflection coil 502. The multipole lens 501c includes the bobbin 101, the hexapole lens metal wire 202, the quadrupole lens metal wire 302, and the deflection coil 502.

The multipole lens according to Modification 2 can virtually shift a lens center of the multipole field by superimposing a deflection field. When the multipole lens has an assembly error or a processing error, the lens center may deviate from an optical axis. This problem can be solved by superimposing the deflection fields as in Modification 2.

### Modification 3

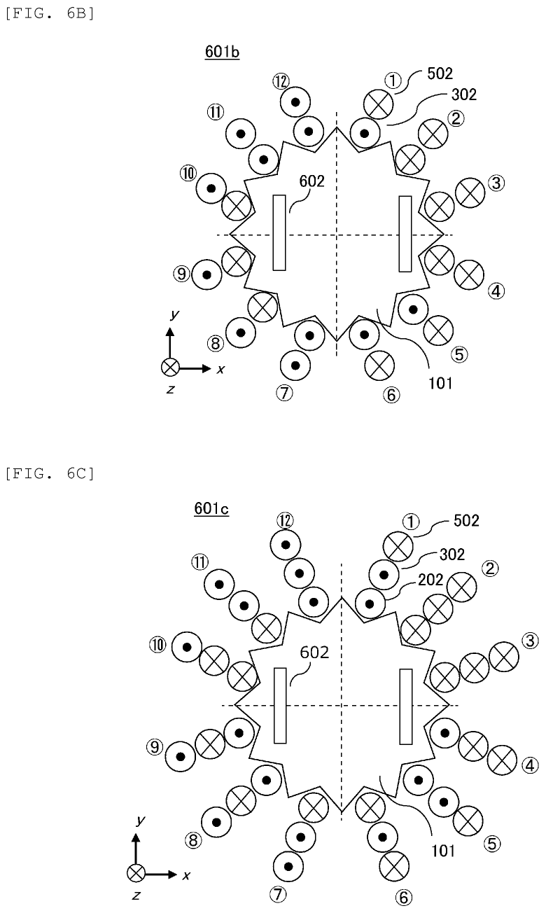

FIGS. 6A to 6C are cross-sectional views showing configurations of multipole lenses 601a to 601c according to Modification 3. In the multipole lenses 601a to 601c, a deflection electrode 602 is provided inside the bobbin 101 forming the multipole lenses 501a to 501c shown as Modification 2. At this time, the deflection electrode 602 is disposed such that an electrostatic deflection field by the deflection electrode 602 is orthogonal to an electromagnetic deflection field by the deflection coil 502, thereby forming an ExB filter. In addition, in order to form the ExB filter, the deflection electrode 602 and the deflection coil 502 are operated such that Wien conditions, in which actions of electrostatic deflection and electromagnetic deflection with respect to a charged particle beam are reversed by the same amount, are satisfied.

The multipole lens 601a functions as a hexapole field lens and an ExB filter, the multipole lens 601b functions as a quadrupole field lens and an ExB filter, and the multipole lens 601c functions as a hexapole field lens, a quadrupole field lens, and an ExB filter.

### Embodiment 2

A charged particle beam device in which the multipole lens described in Embodiment 1 is mounted will be described as Embodiment 2.

### First Example

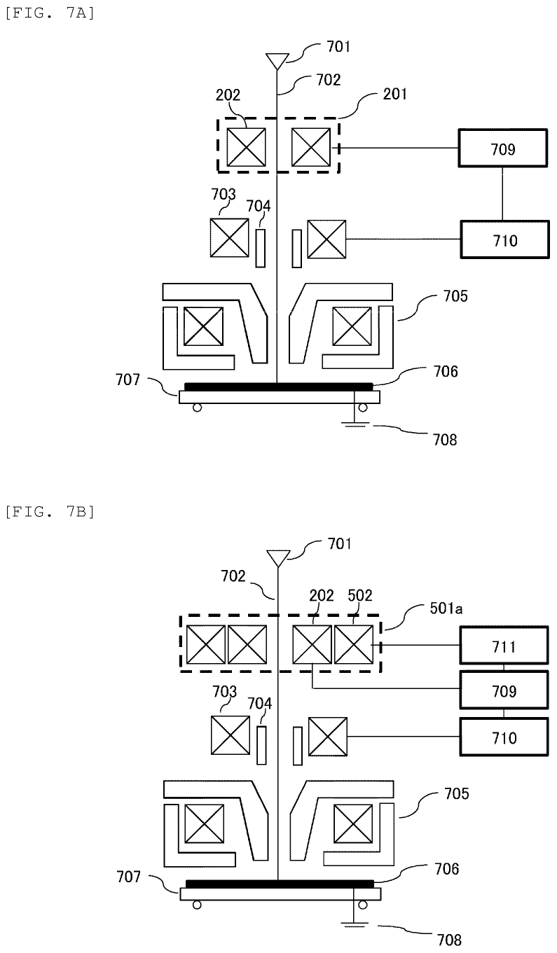

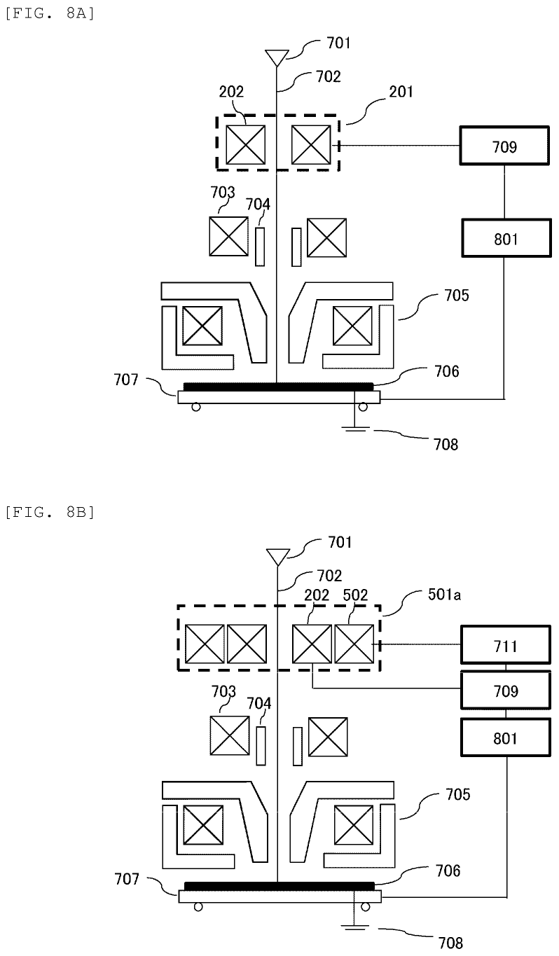

A first example is a charged particle beam device on which a hexapole lens for correcting a deflection coma aberration during image shift deflection is mounted. Each of the charged particle beam devices in FIGS. 7A and 7B includes a hexapole lens for correcting a deflection coma aberration upstream of an image shift deflector.

A charged particle beam 702 generated by a charged particle source 701 passes through the hexapole lens 201 (FIG. 7A) or the deflection coil-superimposed hexapole lens 501a (FIG. 7B), is deflected by an image shift deflector 703 and an imaging deflector 704, is narrowed by an objective lens 705, and enters a sample 706 on a sample stage 707. A retarding voltage source 708 applies, to the sample 706, a retarding voltage necessary for a high resolution. The deflection coil-superimposed hexapole lens 501a in a configuration of FIG. 7B is a multipole lens in which the deflection coil 502 is superimposed on the hexapole lens metal wire 202 (see FIG. 5A), and has a function of virtually shifting a lens center of a hexapole field.

The hexapole lens metal wire 202 forming the hexapole lens 201 or the deflection coil-superimposed hexapole lens 501a is connected to a hexapole lens controller 709, the image shift deflector 703 is connected to an image shift deflector controller 710, and the deflection coil 502 forming the deflection coil-superimposed hexapole lens 501a is connected to a deflection coil controller 711.

With respect to the deflection coma aberration caused by the image shift deflection, a reversed deflection coma aberration is generated by the hexapole lens, and the deflection coma aberrations are cancelled out. In order to perform this process in conjunction with image shift deflection, an output of the hexapole lens controller 709 is controlled in conjunction with an output of the image shift deflector controller 710.

This control condition is expressed by the following (Formula 1), where C_{co_IS} is a deflection coma coefficient of the objective lens associated with the image shift deflection (objective lens image plane equivalent value), ai is an opening angle of a primary beam on an objective lens image plane, IS=(ISX+iISY) is an image shift deflection amount, C_{co_ML} is a deflection coma aberration coefficient by the multipole lens (objective lens object plane equivalent value), S_{ML} is a sensitivity of the multipole lens, I_{ML}=(I_{MLX}+iI_{MLY}) is a use current of the multipole lens, and M is an image magnification of the objective lens.

$$\sqrt{5} {C}_{co\_IS} {α}_{i}^{2} \overline{IS} + \frac{\sqrt{5} {C}_{co\_ML} {α}_{o}^{2} {S}_{ML} \overline{{I}_{ML}}}{M} = 0 \qquad [ Formula 1 ]$$

In (Formula 1), the first term means a deflection coma aberration generated by the image shift deflector, and the second term means a deflection coma aberration generated by the multipole lens. In an ideal multipole lens, a dipole field is zero, but since a slit division number N of a bobbin is finite, a minute dipole field is actually generated. Therefore, the sensitivity S_{ML} of the multipole lens does not become 0, and a relationship between the image shift deflection amount IS and the hexapole lens current I_{ML} that satisfies (Formula 1) is uniquely determined. Accordingly, by controlling the output of the hexapole lens controller 709 that determines the hexapole lens current I_{ML} in accordance with the output of the image shift deflector controller 710 that determines the image shift deflection amount IS so as to satisfy this relationship, wide region image shift deflection without a deflection coma aberration can be implemented.

The deflection coil controller 711 is used to control a current flowing through a deflection coil such that a lens field center of a hexapole lens coincides with an optical axis.

### Second Example

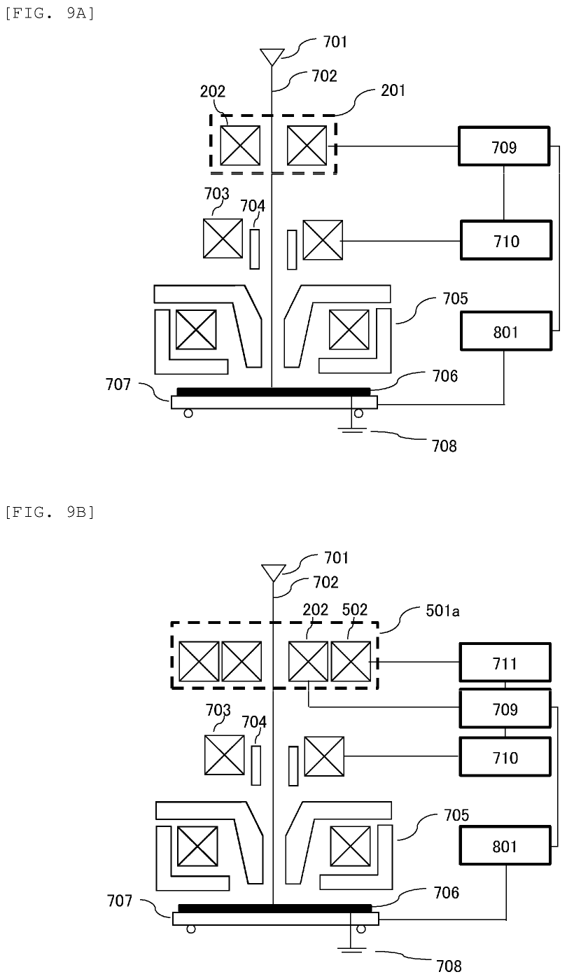

A second example is a charged particle beam device on which a hexapole lens for correcting a deflection coma aberration generated during observation of a wafer end portion is mounted. Each of the charged particle beam devices in FIGS. 8A and 8B includes a hexapole lens for correcting a deflection coma aberration upstream of an image shift deflector. FIG. 8B shows an example in which the deflection coil-superimposed hexapole lens 501a is used as the hexapole lens.

The charged particle beam 702 generated by the charged particle source 701 passes through the hexapole lens 201 (FIG. 8A) or the deflection coil-superimposed hexapole lens 501a (FIG. 8B), is deflected by the image shift deflector 703 and the imaging deflector 704, is narrowed by the objective lens 705, and enters the sample 706 on the sample stage 707 to which a retarding voltage is applied by the retarding voltage source 708. An operation and coordinates of the sample stage 707 are managed by a stage controller 801.

The hexapole lens metal wire 202 forming the hexapole lens 201 or the deflection coil-superimposed hexapole lens 501a is connected to the hexapole lens controller 709, and the deflection coil 502 forming the deflection coil-superimposed hexapole lens 501a is connected to the deflection coil controller 711.

When a visual field is moved to a wafer end portion of a semi-conductor by movement of the stage, a retarding electric field on the sample 706 is disturbed, and a deflection field or a multipole field is generated. With respect to the deflection coma aberration associated therewith, a reversed deflection coma aberration is generated by the hexapole lens, and the deflection coma aberrations are cancelled out. Since this process is performed in conjunction with the movement of the stage, the output of the hexapole lens controller 709 is controlled in conjunction with the output of the stage controller 801.

This control condition is expressed by (Formula 2), where P=(PX+iPY) is stage coordinates, and d_{co_stage}(P) is a deflection coma aberration that is non-linearly generated with respect to the stage coordinates.

$${d}_{co\_stage} ( P ) + \frac{\sqrt{5} {C}_{co\_ML} {α}_{o}^{2} {S}_{ML} \overline{{I}_{ML}}}{M} = 0 \qquad [ Formula 2 ]$$

In (Formula 2), the first term means a deflection coma aberration generated according to the stage coordinates, and the second term means a deflection coma aberration generated by the multipole lens. As described above, since the slit division number N of the bobbin is finite, the sensitivity S_{ML} of the multipole lens does not become 0, and a relationship between stage coordinates P and the hexapole lens current I_{ML} that satisfies (Formula 2) is uniquely determined. Accordingly, by controlling the output of the hexapole lens controller 709 that determines the hexapole lens current I_{ML} in accordance with the output of the stage controller 801 that determines the stage coordinates P so as to satisfy this relationship, observation of a wafer end without a deflection coma aberration can be implemented.

### Third Example

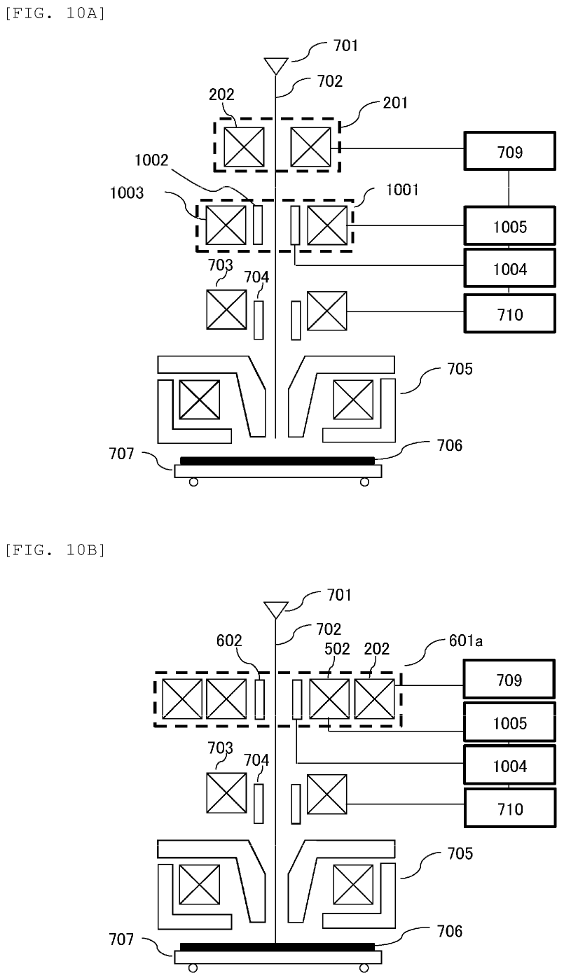

A third example is a charged particle beam device on which a hexapole lens for simultaneously correcting both a deflection coma aberration during image shift deflection and a deflection coma aberration generated during observation of a wafer end portion is mounted. Accordingly, the third example has a configuration (FIGS. 9A and 9B) obtained by combining the configuration of the first example (FIGS. 7A and 7B) and the configuration of the second example (FIGS. 8A and 8B).

In order to simultaneously correct both the deflection coma aberration during the image shift deflection and the deflection coma aberration generated during the observation of the wafer end portion, the output of the hexapole lens controller 709 that determines the hexapole lens current I_{ML} may be controlled in accordance with the output of the image shift deflector controller 710 that determines the image shift deflection amount IS and the output of the stage controller 801 that determines the stage coordinates P such that a relationship (Formula 3) is satisfied.

$${d}_{co\_stage} ( P ) + \sqrt{5} {C}_{co\_IS} {α}_{i}^{2} \overline{IS} + \frac{\sqrt{5} {C}_{co\_ML} {α}_{o}^{2} {S}_{ML} \overline{{I}_{ML}}}{M} = 0 \qquad [ Formula 3 ]$$

### Fourth Example

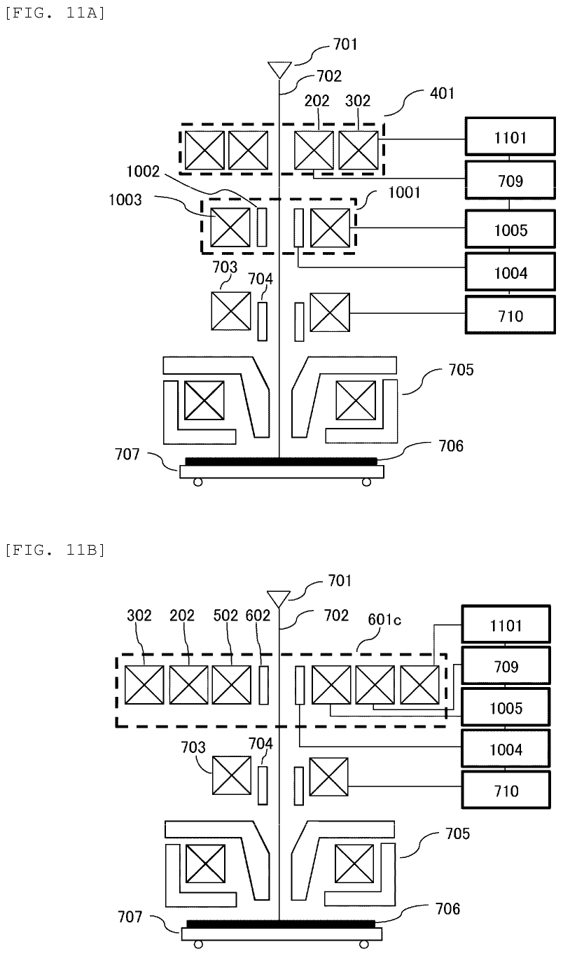

A fourth example is a charged particle beam device on which a hexapole lens and an ExB filter for simultaneously correcting both a deflection coma aberration and a deflection color aberration during image shift deflection is mounted. A configuration in which an ExB filter 1001 and the hexapole lens 201 are disposed in multiple stages (FIG. 10A) and a configuration in which the ExB filter-mounted hexapole lens 601a is used (FIG. 10B) are shown.

In the charged particle beam device in FIG. 10A, the hexapole lens metal wire 202 forming the hexapole lens 201 is connected to the hexapole lens controller 709, the image shift deflector 703 is connected to the image shift deflector controller 710, a deflection electrode 1002 forming the ExB filter 1001 is connected to a deflection electrode controller 1004, and a deflection coil 1003 forming the ExB filter 1001 is connected to a deflection coil controller 1005.

In the charged particle beam device in FIG. 10B, the hexapole lens metal wire 202 forming the ExB filter-mounted hexapole lens 601a (see FIG. 6A) is connected to the hexapole lens controller 709, the deflection electrode 602 forming the ExB filter-mounted hexapole lens 601a is connected to the deflection electrode controller 1004, the deflection coil 502 forming the ExB filter-mounted hexapole lens 601a is connected to the deflection coil controller 1005, and the image shift deflector 703 is connected to the controller 710.

Here, the deflection electrode controller 1004 and the deflection coil controller 1005 control a voltage of the deflection electrode 602 and a current of the deflection coil 502 under a condition that the Wien condition is satisfied.

In order to simultaneously correct both the deflection coma aberration and the deflection color aberration during the image shift deflection, the output of the hexapole lens controller 709 that determines the hexapole lens current I_{ML}, an output of the deflection electrode controller 1004 that determines a voltage V_{ExB} of the ExB filter, and an output of the deflection coil controller 1005 that determines a current I_{ExB} of the ExB filter are controlled according to the output of the image shift deflector controller 710 that determines the image shift deflection amount IS so as to satisfy the following relationships (Formula 4) and (Formula 5). In (Formula 4) and (Formula 5), the following variables are newly defined.
c_{Cc_IS}: deflection color aberration coefficient of objective lens associated with image shift deflection (objective lens image plane equivalent value)
V_{acc}: acceleration voltage of primary beam
dV: energy dispersion of primary beam
C_{E}_: deflection coma aberration coefficient of ExB deflection electrode (objective lens object plane equivalent value)
C_{co_B}: deflection coma aberration coefficient of ExB deflection coil (objective lens object plane equivalent value)
C_{Cc_E}: deflection color aberration coefficient of ExB deflection electrode (objective lens object plane equivalent value)
C_{Cc_B}: deflection color aberration coefficient of ExB deflection coil (objective lens object plane equivalent value)
S_{E}: deflection sensitivity of ExB deflection electrode
S_{B}: deflection sensitivity of ExB deflection coil

$$\sqrt{5} {C}_{co\_IS} {α}_{i}^{2} \overline{IS} + {C}_{Cc\_IS} IS \frac{dV}{{V}_{acc}} + \frac{\sqrt{5} {C}_{co\_ML} {α}_{o}^{2} {S}_{ML} \overline{{I}_{ML}}}{M} + \frac{\sqrt{5} ( {C}_{co\_E} - {C}_{co\_B} ) {α}_{o}^{2} {S}_{E} \overline{{V}_{E \times B}}}{M} + \frac{( {C}_{Cc\_E} - {C}_{Cc\_B} ) {S}_{E} {V}_{E \times B} \frac{dV}{{V}_{0}}}{M} = 0 \qquad [ Formula 4 ]$$

$${S}_{E} {V}_{E \times B} = {S}_{B} {I}_{E \times B} \qquad [ Formula 5 ]$$

In (Formula 4), the first term and the second term on the left side respectively mean the deflection coma aberration and the deflection color aberration caused by the image shift deflection. In addition, the third term on the left side means the deflection coma aberration by the hexapole lens, and the fourth term and the fifth term on the left side respectively mean the deflection coma aberration and the deflection color aberration by the ExB filter. When the relationship (Formula 4) is satisfied, the deflection coma aberration and the deflection color aberration caused by the image shift deflection are simultaneously corrected by the hexapole lens and the ExB filter. In addition, (Formula 5) means the Wien condition. Accordingly, by performing control so as to simultaneously satisfy (Formula 4) and (Formula 5), the deflection coma aberration and the deflection color aberration caused by the image shift deflection can be simultaneously corrected.

### Fifth Example

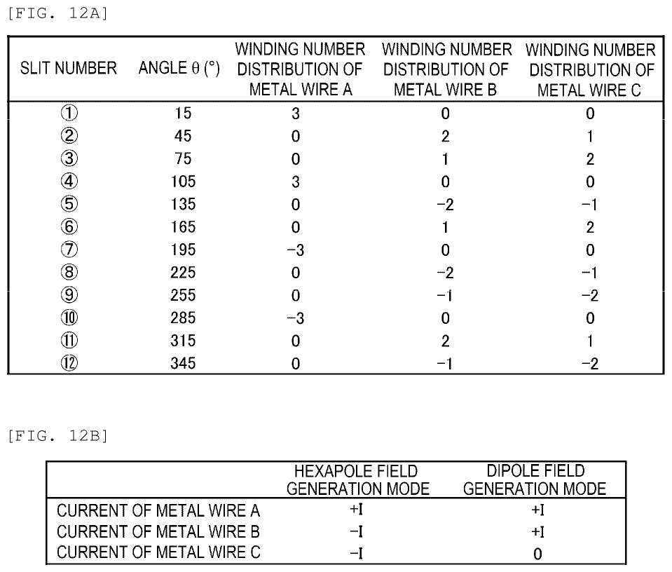

In a fifth example, the charged particle beam device in the fourth example is functionally extended, and a quadrupole lens is superimposed on a hexapole lens. By mounting the quadrupole lens, it is possible to correct a parasitic deflection astigmatism caused by the hexapole lens or an ExB filter and a deflection astigmatism caused by image shift deflection. A configuration in which the ExB filter 1001 and the quadrupole lens-superimposed hexapole lens 401 are disposed in multiple stages (FIG. 11A) and a configuration in which the ExB filter and quadrupole lens-superimposed hexapole lens 601c is used (FIG. 11B) are shown.

In the charged particle beam device shown in FIG. 11A, the hexapole lens metal wire 202 forming the quadrupole lens-superimposed hexapole lens 401 (see FIG. 4) is connected to the hexapole lens controller 709, the quadrupole lens metal wire 302 is connected to a quadrupole lens controller 1101, the image shift deflector 703 is connected to the image shift deflector controller 710, the deflection electrode 1002 forming the ExB filter 1001 is connected to the controller 1004, and the deflection coil 1003 is connected to the deflection coil controller 1005.

In the charged particle beam device shown in FIG. 11B, the hexapole lens metal wire 202 forming the ExB filter and quadrupole lens-superimposed hexapole lens 601c (see FIG. 6C) is connected to the hexapole lens controller 709, the quadrupole lens metal wire 302 is connected to the quadrupole lens controller 1101, the deflection electrode 602 is connected to the deflection electrode controller 1004, the deflection coil 502 is connected to the deflection coil controller 1005, and the image shift deflector 703 is connected to the image shift deflector controller 710.

In order to correct the parasitic deflection astigmatism caused by the hexapole lens and the ExB filter and the deflection astigmatism caused by the image shift deflection, the output of the hexapole lens controller 709 that determines the hexapole lens current I_{ML}, an output of the quadrupole lens controller 1101 that determines a quadrupole lens current I_{ML2}, the output of the deflection electrode controller 1004 that determines the voltage V_{ExB} of the ExB filter, and the output of the deflection coil controller 1005 that determines the current I_{ExB} of the ExB filter are controlled according to the output of the image shift deflector controller 710 that determines the image shift deflection amount IS so as to simultaneously satisfy (Formula 5) meaning the Wien condition and the following (Formula 6). In (Formula 6), the following variables are newly defined.
C_{As}: sum of parasitic deflection astigmatism coefficient and deflection astigmatism coefficient in objective lens caused by image shift deflection (objective lens image plane equivalent value)
C_{As_ML2}: deflection astigmatism coefficient by multipole lens for generating quadrupole field (objective lens object plane equivalent value)
S_{ML}: sensitivity of multipole lens for generating quadrupole field

$$\sqrt{5} {C}_{co\_IS} {α}_{i}^{2} \overline{IS} + {C}_{Cc\_IS} IS \frac{dV}{{V}_{acc}} + 2 {C}_{As} \overline{{α}_{i}} {IS}^{2} + \frac{\sqrt{5} {C}_{co\_ML} {α}_{o}^{2} {S}_{ML} \overline{{I}_{ML}}}{M} + \frac{\sqrt{5} ( {C}_{co\_E} - {C}_{co\_B} ) {α}_{o}^{2} {S}_{E} \overline{{V}_{E \times B}}}{M} + \frac{( {C}_{Cc\_E} - {C}_{Cc\_B} ) {S}_{E} {V}_{E \times B} \frac{dV}{{V}_{0}}}{M} = 2 {C}_{As} {\overline{α}}_{i} {IS}^{2} + \frac{2 {C}_{As\_ML 2} {\overline{{α}_{0}} ( {S}_{ML 2} \overline{{I}_{ML 2}} )}^{2}}{M} 0 \qquad [ Formula 6 ]$$

In (Formula 6), the first to fifth terms on the left side mean the same content as the left side of (Formula 5). The sixth term on the left side means the sum of the parasitic deflection astigmatism and the deflection astigmatism caused by the image shift deflection, and the seventh term on the left side means the deflection astigmatism caused by the multipole lens for generating the quadrupole field. When (Formula 6) is satisfied, the deflection coma aberration, deflection color aberration, and deflection astigmatism caused by the image shift deflection and the deflection astigmatism caused by the parasitic aberration are simultaneously corrected by the hexapole lens, the ExB filter, and the quadrupole lens.

### Embodiment 3

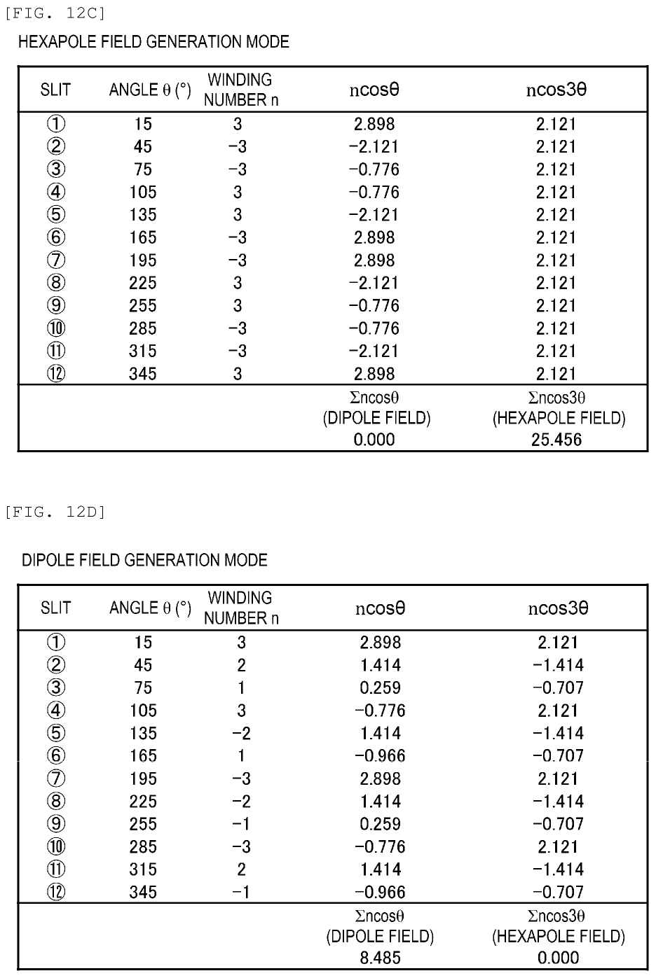

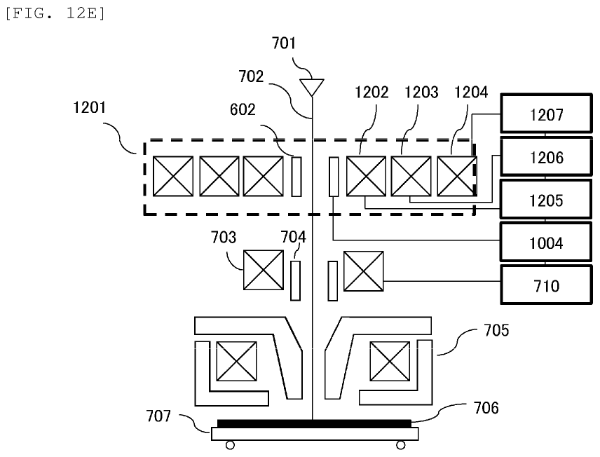

FIG. 12A is a table showing a winding number distribution of a multipole lens according to Embodiment 3. The multipole lens according to Embodiment 3 generates and switches between a hexapole field and a dipole field. A sign of the winding number distribution indicates a direction in which a metal wire passes through a slit. In order to implement this function, as shown in the table of FIG. 12A, three types of metal wires A, B, and C having different winding number distributions are wound around and superimposed on a bobbin described in Embodiment 1. FIG. 12A is an example when N=1, but is not limited to this value. When N is larger than 1, a cross section of the bobbin orthogonal to a longitudinal direction of the slit is divided into 12 regions having an equal central angle, and the metal wire is wound around the bobbin such that the slits provided in the respective regions have the winding number distributions described in the table of FIG. 12A. That is, when the first to twelfth regions are defined in order along a circumferential direction of the bobbin, slit numbers in FIG. 12A may be read as region numbers.

FIG. 12B is a table showing a method of controlling the multipole lens according to Embodiment 3. When the hexapole field is generated (hexapole field generation mode), a direct current +I is applied to the metal wire A, and a direct current −I in an opposite direction is applied to the metal wires B and C with the same current amount. Accordingly, a current line distribution by the metal wires A, B, and C coincides with that of a hexapole lens. FIG. 12C is a table showing the winding number distribution of the multipole lens (hexapole field generation mode) according to Embodiment 3, and simple calculation results of the dipole field and the hexapole field. Columns in the table are the same as columns in the table shown in FIG. 2B. A value of a winding number n is obtained based on the winding number distribution of the metal wire shown in FIG. 12A and a current applied to the metal wire in the hexapole field generation mode shown in FIG. 12B. The winding number n of a slit 1 is 3 when the current +I is applied only to the metal wire A having a winding number distribution 3. The winding number n of a slit 2 is −3 when the current −I is applied to the metal wire B having a winding number distribution 2 and the metal wire C having a winding number distribution 1. It is understood from the table of FIG. 12C that the multipole lens according to Embodiment 3 generates the hexapole field without generating the dipole field, that is, functions as the hexapole lens.

Regarding this, when the dipole field is generated (dipole field generation mode), as shown in the table of FIG. 12B, the same amount of the direct current +I in the same direction is applied to the metal wire A and the metal wire B, and no current is applied to the metal wire C. Accordingly, the current line distribution by the metal wires A, B, and C coincides with that of a cosine winding deflection coil. FIG. 12D is a table showing the winding number distribution of the multipole lens (dipole field generation mode) according to Embodiment 3, and the simple calculation results of the dipole field and the hexapole field. Columns in the table are also the same as the columns in the table shown in FIG. 2B. It is understood from the table of FIG. 12D that the multipole lens according to Embodiment 3 generates the dipole field without generating the hexapole field, that is, functions as a dipole lens.

By providing a deflection electrode inside the bobbin forming the multipole lens according to Embodiment 3, an ExB filter can be formed when the dipole field is generated. With such a configuration, the ExB filter for correcting a deflection color aberration and the hexapole lens for correcting a deflection coma aberration can be switched by switching the control shown in the table of FIG. 12B.

FIG. 12E shows a configuration example of a charged particle beam device on which the multipole lens according to the embodiment is mounted. The charged particle beam 702 generated by the charged particle source 701 passes through a dipole field and hexapole field-switched multipole lens 1201, is deflected by the image shift deflector 703 and the imaging deflector 704, is narrowed by the objective lens 705, and enters the sample 706 on the sample stage 707. The deflection electrode 602 is disposed inside the bobbin of the dipole field and hexapole field-switched multipole lens 1201.

A metal wire A 1202, a metal wire B 1203, and a metal wire C 1204 forming the dipole field and hexapole field-switched multipole lens 1201 are controlled by different controllers 1205, 1206, and 1207, respectively. When dipole field and hexapole field-switched multipole lens 1201 is operated in the dipole field generation mode, the deflection electrode 602 is controlled by the controller 1004 such that Wien conditions with the dipole field are satisfied.

According to the charged particle beam device shown in FIG. 12E, it is possible to selectively perform deflection color aberration correction and deflection coma aberration correction by switching functions of the ExB filter and the hexapole lens. As for a deflection aberration during image shift, since the deflection color aberration is dominant during a low acceleration and the deflection coma aberration is dominant during a high acceleration, there may be a case where it is not necessary to simultaneously correct both of the deflection color aberration and the deflection coma aberration. Accordingly, the charged particle beam device according to Embodiment 3 can be used for selectively correcting the deflection color aberration and the deflection coma aberration according to an acceleration voltage to be used.

Such switching functions of the ExB filter and the hexapole lens can be performed by independently superimposing a coil for generating the dipole field and the hexapole lens, but a total of the winding numbers of the wires can be saved by the embodiment. The saving of the winding numbers is useful for reducing assembly errors due to the superimposing and winding of the coil.

The invention is not limited to the above-described embodiments, and includes various modifications. The embodiments and the modifications described above are described in detail in order to facilitate understanding of the invention, and the invention is not necessarily limited to those including all the configurations described above. A part of the configurations of one embodiment and one modification may be replaced with configurations of other embodiments and modifications. The configurations of one embodiment and one modification can be added to configurations of other embodiments and modifications. Other configurations may be added to, deleted from, or replaced with a part of the configurations of the embodiments and the modifications.

### REFERENCE SIGNS LIST

101: bobbin
201: hexapole lens
202: hexapole lens metal wire
301: quadrupole lens
302: quadrupole lens metal wire
401: quadrupole lens-superimposed hexapole lens
501: deflection coil-superimposed multipole lens
502: deflection coil
601: ExB filter-mounted multipole lens
602: deflection electrode
701: charged particle source
702: charged particle beam
703: image shift deflector
704: imaging deflector
705: objective lens
706: sample
707: sample stage
708: retarding voltage source
709: hexapole lens controller
710: image shift deflector controller
711: deflection coil controller
801: stage controller
1001: ExB filter
1002: deflection electrode
1003: deflection coil
1004: deflection electrode controller
1005: deflection coil controller
1101: quadrupole lens controller
1201: dipole field and hexapole field-switched multipole lens
1202: metal wire A
1203: metal wire B
1204: metal wire C
1205: controller for metal wire A
1206: controller for metal wire B
1207: controller for metal wire C

1. A multipole lens comprising:
a hollow cylindrical non-magnetic bobbin provided with a plurality of slits; and
a metal wire, wherein
the non-magnetic bobbin includes a slit portion provided with the plurality of slits and first and second circumferential portions provided to sandwich the slit portion,
the plurality of slits are disposed such that a central angle between adjacent slits is (360/12N)°, N being a natural number,
the metal wire is wound around the non-magnetic bobbin so as to repeat passing through a certain slit among the plurality of slits from the first circumferential portion toward the second circumferential portion, moving from the certain slit along the second circumferential portion to another slit among the plurality of slits, passing through the other slit from the second circumferential portion toward the first circumferential portion, and moving from the other slit along the first circumferential portion to still another slit among the plurality of slits,
winding numbers of the metal wire in the plurality of slits are equal, and
when a cross section of the non-magnetic bobbin orthogonal to a longitudinal direction of the slits is divided into an even number of regions having an equal central angle and including two or more of the slits, directions in which the metal wire passes through the slits provided in the region are same, and a direction in which the metal wire passes through the slits provided in the adjacent region is reversed.

2. The multipole lens according to claim 1, wherein
among the slits provided in the region, a central angle between the metal wire in two slits closest to a boundary between the adjacent regions is in a range of 60°±3°, and
the metal wire is wound n₁ times per slit, n₁ being a natural number.

3. The multipole lens according to claim 1, wherein
among the slits provided in the region, a central angle between the metal wire in two slits closest to a boundary between the adjacent regions is in a range of 90°±3°, and
the metal wire is wound n₂ times per slit, n₂ being a natural number.

4. The multipole lens according to claim 1, wherein
a first metal wire and a second metal wire are superimposed on each other as the metal wire wound around the non-magnetic bobbin, and
a central angle of the region defining a passing direction of the first metal wire through the slit is different from a central angle of the region defining a passing direction of the second metal wire through the slit.

5. The multipole lens according to claim 4, wherein
the central angle of the region for the first metal wire divides the cross section of the non-magnetic bobbin into six or four sections, and the central angle of the region for the second metal wire divides the cross section of the non-magnetic bobbin into two sections.

6. The multipole lens according to claim 4, wherein
the central angle of the region for the first metal wire divides the cross section of the non-magnetic bobbin into six sections, and the central angle of the region for the second metal wire divides the cross section of the non-magnetic bobbin into four sections.

7. The multipole lens according to claim 6, wherein
a third metal wire is further superimposed as the metal wire wound around the non-magnetic bobbin, and
a central angle of the region for the third metal wire divides the cross section of the non-magnetic bobbin into two sections.

8. The multipole lens according to claim 5, further comprising:
a deflection electrode disposed in the non-magnetic bobbin.

9. A charged particle beam device comprising:
a sample stage on which a sample is to be mounted;
a charged particle beam optical system including an image shift deflector that moves an irradiation point of a charged particle beam on the sample, and the multipole lens according to claim 1;
an image shift deflector controller configured to control the image shift deflector; and
a multipole lens controller connected to the metal wire of the multipole lens and configured to control generation of a multipole field in the multipole lens.

10. The charged particle beam device according to claim 9, wherein
a central angle of the region for the metal wire divides the cross section of the non-magnetic bobbin into six sections, and
the multipole lens controller is configured to control the multipole lens in conjunction with the image shift deflector controller such that a deflection coma aberration generated by the image shift deflector is cancelled by a deflection coma aberration generated by the multipole lens.

11. The charged particle beam device according to claim 9, further comprising:
a retarding voltage source configured to apply a retarding voltage to the sample; and
a sample stage controller configured to control the sample stage, wherein
the central angle of the region for the metal wire divides the cross section of the non-magnetic bobbin into six sections, and
the multipole lens controller is configured to control the multipole lens based on stage coordinates managed by the sample stage controller such that a deflection coma aberration generated when an end portion of the sample is observed is cancelled by a deflection coma aberration generated by the multipole lens.

12. The charged particle beam device according to claim 9, further comprising:
a deflection coil controller; and
a deflection electrode controller, wherein
the charged particle beam optical system includes an ExB filter including a deflection coil and a deflection electrode,
the deflection coil controller is configured to control the deflection coil, and the deflection electrode controller is configured to control the deflection electrode,
the deflection coil controller and the deflection electrode controller are configured to control the ExB filter such that a Wien condition is satisfied and a deflection color aberration generated by the image shift deflector is cancelled by a deflection color aberration generated by the ExB filter,
the central angle of the region for the metal wire divides the cross section of the non-magnetic bobbin into six sections, and
the multipole lens controller is configured to control the multipole lens in conjunction with the image shift deflector controller, the deflection coil controller, and the deflection electrode controller such that a deflection coma aberration generated by the image shift deflector and the ExB filter is cancelled by a deflection coma aberration generated by the multipole lens.

13. The charged particle beam device according to claim 9, further comprising:
a deflection coil controller; and
a deflection electrode controller, wherein
a first metal wire and a second metal wire are superimposed on each other as the metal wire wound around the non-magnetic bobbin, a central angle of the region for the first metal wire divides the cross section of the non-magnetic bobbin into six sections, a central angle of the region for the second metal wire divides the cross section of the non-magnetic bobbin into two sections, a deflection electrode is disposed in the non-magnetic bobbin, and the multipole lens is an ExB filter-mounted hexapole lens,
the deflection coil controller is connected to the second metal wire and is configured to control generation of a deflection field in the ExB filter-mounted hexapole lens, and the deflection electrode controller is configured to control the deflection electrode,
the multipole lens controller is connected to the first metal wire,
the deflection coil controller and the deflection electrode controller are configured to control the ExB filter such that a Wien condition is satisfied and a deflection color aberration generated by the image shift deflector is cancelled by a deflection color aberration generated by the ExB filter, and
the multipole lens controller is configured to control generation of a hexapole field in conjunction with the image shift deflector controller, the deflection coil controller, and the deflection electrode controller such that a deflection coma aberration generated by the image shift deflector and the ExB filter is cancelled by a deflection coma aberration generated by the ExB filter-mounted hexapole lens.

14. The charged particle beam device according to claim 9, wherein
a central angle of the region for the metal wire divides the cross section of the non-magnetic bobbin into four sections, and
the multipole lens controller is configured to control the multipole lens in conjunction with the image shift deflector controller such that a deflection astigmatism caused by image shift deflection of the charged particle beam is cancelled by a deflection astigmatism generated by the multipole lens.

15. A multipole lens comprising:
a hollow cylindrical non-magnetic bobbin provided with a plurality of slits; and
a metal wire, wherein
the non-magnetic bobbin includes a slit portion provided with the plurality of slits and first and second circumferential portions provided to sandwich the slit portion,
the plurality of slits are disposed such that a central angle between adjacent slits is (360/12N)°, N being a natural number,
the metal wire is wound around the non-magnetic bobbin so as to repeat passing through a certain slit among the plurality of slits from the first circumferential portion toward the second circumferential portion, moving from the certain slit along the second circumferential portion to another slit among the plurality of slits, passing through the other slit from the second circumferential portion toward the first circumferential portion, and moving from the other slit along the first circumferential portion to still another slit among the plurality of slits,
a first metal wire, a second metal wire, and a third metal wire are superimposed as the metal wire wound around the non-magnetic bobbin,
when a cross section of the non-magnetic bobbin orthogonal to a longitudinal direction of the slits is divided into 12 regions having an equal central angle and including one or more of the slits, the 12 regions are defined as first to twelfth regions in order along a circumferential direction of the non-magnetic bobbin, a direction from the first circumferential portion toward the second circumferential portion along the slit is defined as a first direction, and a direction from the second circumferential portion toward the first circumferential portion along the slit is defined as a second direction, and n₃ is a natural number,
the first metal wire is wound 3n₃ times in the first direction in the slits provided in the first region, is wound 3n₃ times in the first direction in the slits provided in the fourth region, is wound 3n₃ times in the second direction in the slits provided in the seventh region, and is wound 3n₃ times in the second direction in the slits provided in the tenth region,
the second metal wire is wound 2n₃ times in the first direction in the slits provided in the second region, is wound n₃ times in the first direction in the slits provided in the third region, is wound 2n₃ times in the second direction in the slits provided in the fifth region, is wound n₃ times in the first direction in the slits provided in the sixth region, is wound 2n₃ times in the second direction in the slits provided in the eighth region, is wound n₃ times in the second direction in the slits provided in the ninth region, is wound 2n₃ times in the first direction in the slits provided in the eleventh region, and is wound n₃ times in the second direction in the slits provided in the twelfth region, and
the third metal wire is wound n₃ times in the first direction in the slits provided in the second region, and is wound 2n₃ times in the first direction in the slits provided in the third region, is wound n₃ times in the second direction in the slits provided in the fifth region, is wound 2n₃ times in the first direction in the slits provided in the sixth region, is wound n₃ times in the second direction in the slits provided in the eighth region, is wound 2n₃ times in the second direction in the slits provided in the ninth region, is wound n₃ times in the first direction in the slits provided in the eleventh region, and is wound 2n₃ times in the second direction in the slits provided in the twelfth region.

16. The multipole lens according to claim 15, further comprising:
a deflection electrode disposed in the non-magnetic bobbin.

17. A charged particle beam device comprising:
a sample stage on which a sample is to be mounted;
a charged particle beam optical system including an image shift deflector configured to move an irradiation point of a charged particle beam on the sample, and the multipole lens according to claim 15;
an image shift deflector controller configured to control the image shift deflector;
a first controller connected to the first metal wire of the multipole lens;
a second controller connected to the second metal wire of the multipole lens; and
a third controller connected to the third metal wire of the multipole lens, wherein
in a hexapole field generation mode in which a hexapole field is generated in the multipole lens, the first controller is configured to apply a first direct current to the first metal wire, and the second controller and the third controller are configured to respectively apply a second direct current to the second metal wire and the third metal wire, the second direct current having a current amount same as the first direct current and having a reverse direction with respect to the first direct current, and
in a dipole field generation mode in which a dipole field is generated in the multipole lens, the first controller and the second controller are configured to respectively apply a third direct current to the first metal wire and the second metal wire in a same direction with a same current amount, and the third controller does not apply a direct current to the third metal wire.
